(19) United States
(12) Patent Application Publication
(10) Pub. No.: US 2026/0013072 A1
(43) Pub. Date: Jan. 8, 2026

(54) COLD PLATE

(71) Applicant: Wiwynn Corporation, New Taipei City (TW)

(72) Inventors: Yi Cheng, New Taipei City (TW); CHIH-CHENG CHIEN, New Taipei City (TW); Shao Yu Liao, New Taipei City (TW)

(21) Appl. No.: 19/256,329

(22) Filed: Jul. 1, 2025

Related U.S. Application Data
(60) Provisional application No. 63/667,261, filed on Jul. 3, 2024.

(30) Foreign Application Priority Data
Jan. 3, 2025 (TW) 114100264

(51) Int. Cl. H05K 7/20

(52) U.S. Cl. CPC H05K 7/20254

(57) ABSTRACT

A cold plate is configured to be thermally coupled to a heat source. The cold plate includes a casing and a plurality of heat exchange structures. The casing has an inlet, a heat exchange chamber and an outlet, and the inlet and the outlet communicate with the heat exchange chamber. The heat exchange structures are located in the heat exchange chamber and arranged in rows. A plurality of channels are formed between the rows of the heat exchange structures. The heat exchange structures in each row are spaced apart from one another so as to form a plurality of slots. The slots communicate with adjacent two of the channels, and each of the slots are formed by curved edges of adjacent two of the heat exchange structures in each row.

### CROSS-REFERENCE TO RELATED APPLICATIONS

This non-provisional application claims priority under 35 U.S.C. § 119(a) on Provisional Application No(s). 63/667,261 filed in U.S.A. on Jul. 3, 2024, and Patent Application No(s). 114100264 filed in Taiwan, R.O.C. on Jan. 3, 2025, the entire contents of which are hereby incorporated by reference.

### TECHNICAL FIELD

The disclosure relates to a cold plate.

### BACKGROUND

With the advancement and development of technology, the performance of processors (such as central processing units or graphics processing units) in electronic devices has become increasingly powerful, but heat generated by them has also increased. In order to effectively dissipate heat from the processor, a cold plate is currently used to be thermally coupled with the processor, allowing the heat generated by the processor to be conducted to the cold plate, and is carried away by the coolant flowing through the cold plate.

Generally, the cold plate is provided with fin structures in sheet shape or plate shape to increase the contact area between the coolant and the cold plate, thereby improving heat exchange efficiency. However, the heat exchange efficiency of the current cold plate is difficult to be further improved, making it unable to handle greater amount of heat generated by more powerful processors. In light of this, researchers in this field are currently working to solve the aforementioned issues.

### SUMMARY

The disclosure provides a cold plate which has an improved heat exchange efficiency to deal with the increasing amount of heat generated by the heat source.

One embodiment of the disclosure provides a cold plate. The cold plate is configured to be thermally coupled to a heat source. The cold plate includes a casing and a plurality of heat exchange structures. The casing has an inlet, a heat exchange chamber and an outlet, and the inlet and the outlet communicate with the heat exchange chamber. The heat exchange structures are located in the heat exchange chamber and arranged in rows. A plurality of channels are formed between the rows of the heat exchange structures. The heat exchange structures in each row are spaced apart from one another so as to form a plurality of slots. The slots communicate with adjacent two of the channels, and each of the slots are formed by curved edges of adjacent two of the heat exchange structures in each row.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 shows a perspective view of a cold plate according to some embodiments of the disclosure;

FIG. 2 shows a cross-sectional view of a cold plate according to some embodiments of the disclosure;

FIG. 3 shows a partially enlarged cross-sectional view of a cold plate according to some embodiments of the disclosure;

FIG. 4 shows another cross-sectional view of a cold plate according to some embodiments of the disclosure;

FIG. 5 shows a top view of a cold plate according to some embodiments of the disclosure;

FIG. 6 shows a partially enlarged top view of a cold plate according to some embodiments of the disclosure;

FIG. 7 shows a perspective view of a cold plate according to some embodiments of the disclosure;

FIG. 8 shows a cross-sectional view of a cold plate according to some embodiments of the disclosure;

FIG. 9 shows a partially enlarged top view of a cold plate according to some embodiments of the disclosure; and

FIG. 10 shows a partially enlarged top view of a cold plate according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

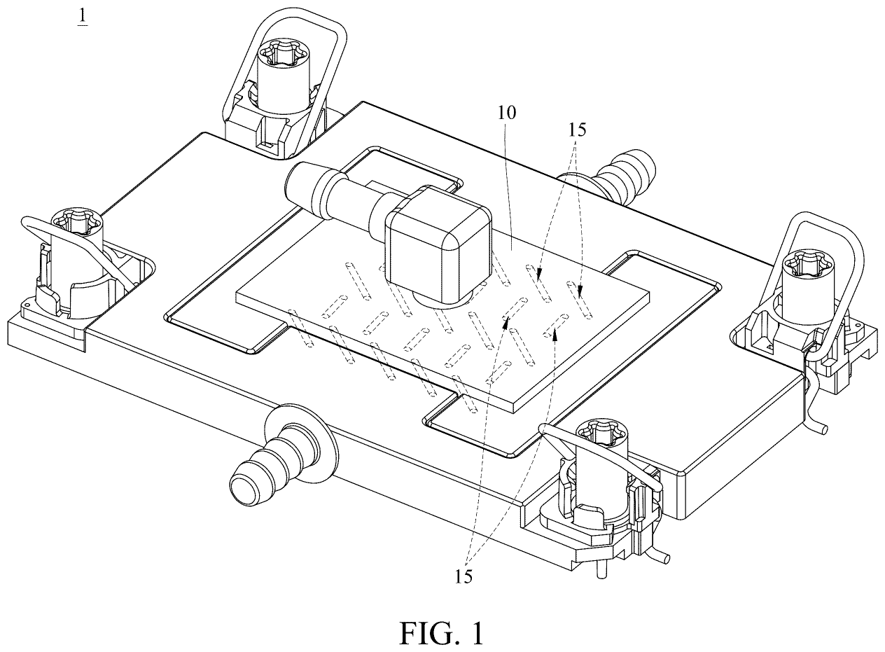

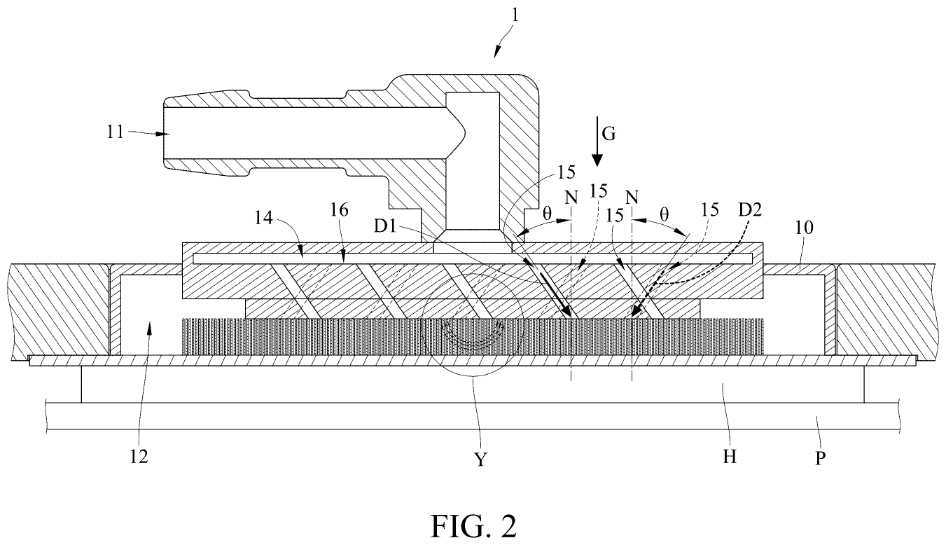

Referring to FIGS. 1 and 2, FIG. 1 shows a perspective view of a cold plate 1 according to some embodiments of the disclosure, and FIG. 2 shows a cross-sectional view of the cold plate 1 according to some embodiments of the disclosure. The structural configurations shown in FIGS. 1 and 2 can be applied to other embodiments of the disclosure.

The cold plate 1 is configured to be thermally coupled to a heat source H on a circuit board P. In some embodiments, the heat source H is, for example, a CPU or a GPU.

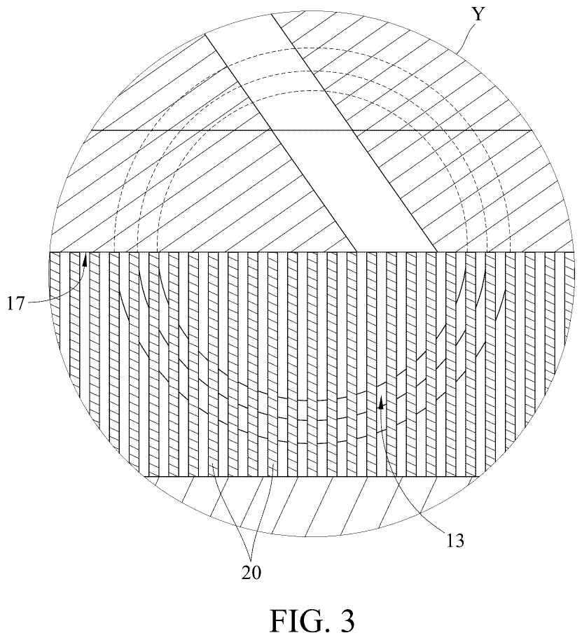

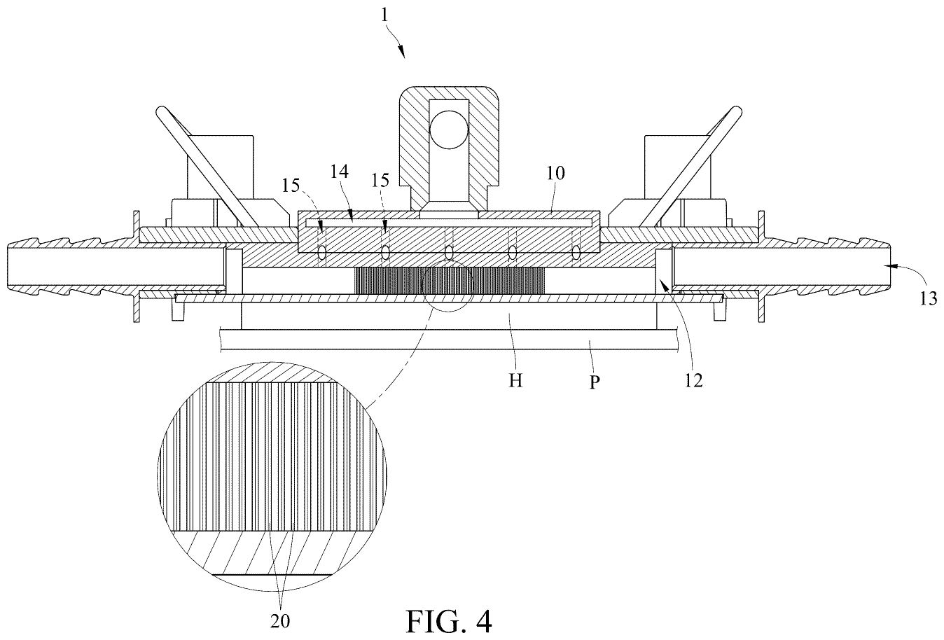

Then, referring to FIGS. 2 to 4. FIG. 3 shows a partially enlarged cross-sectional view of the cold plate 1 according to some embodiments of the disclosure. In some embodiments, FIG. 3 shows a partially enlarged cross-sectional view of an area Y in FIG. 2. FIG. 4 shows another cross-sectional view of the cold plate 1 according to some embodiments of the disclosure. The structural configurations shown in FIGS. 3 and 4 can be applied to other embodiments of the disclosure.

The cold plate 1 includes a casing 10 and a plurality of heat exchange structures 20. The casing 10 has an inlet 11, a heat exchange chamber 12 and at least one outlet 13. The inlet 11 and the outlet 13 communicate with the heat exchange chamber 12. The heat exchange structures 20 are located in the heat exchange chamber 12.

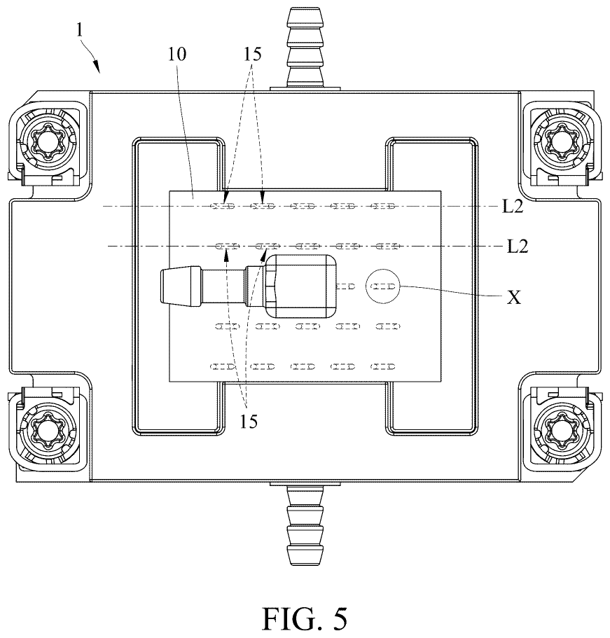

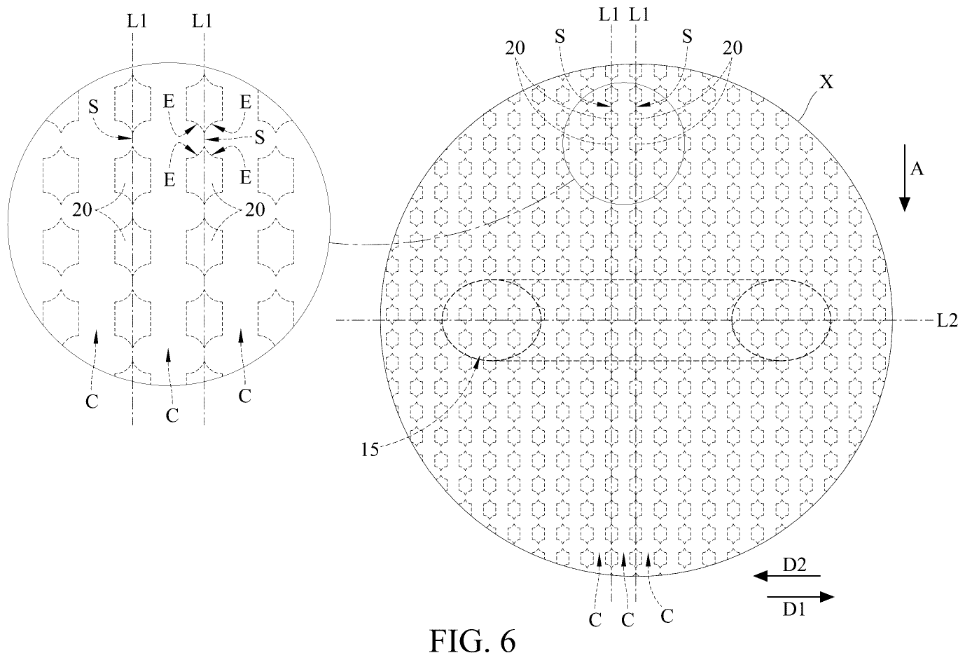

Then, referring to FIGS. 5 and 6. FIG. 5 shows a top view of the cold plate 1 according to some embodiments of the disclosure. FIG. 6 shows a partially enlarged top view of the cold plate 1 according to some embodiments of the disclosure. In some embodiments, FIG. 6 shows a partially enlarged top view of an area X in FIG. 5. The structural configurations shown in FIGS. 5 and 6 can be applied to other embodiments of the disclosure.

The heat exchange structures 20 are arranged in rows. A plurality of channels C are formed between the rows of the heat exchange structures 20. The heat exchange structures 20 in each row are spaced apart from one another so as to form a plurality of slots S.

The slots S communicate with adjacent two of the channels C. In some embodiments, each of the slots is formed by curved edges E of adjacent two of the heat exchange structures 20 in each row. In some embodiments, edges of the heat exchange structures 20 forming the slots S may be entirely or partially curved.

In some embodiments, as shown in FIG. 6, the heat exchange structures 20 are arranged in the rows along straight lines L1 which are parallel to and spaced from one another. For example, in some embodiments, the heat exchange structures 20 are arranged in an array, but the disclosure is not limited thereto. The arrangement of the heat exchange structures can be adjusted according to the position of the heat source corresponding to the heat exchange chamber as long as the heat exchange structures can form channels and slots communicating with these channels. For example, in some embodiments, when the heat source corresponds to a corner of the heat exchange chamber, the positions of these heat exchange structures can be correspondingly adjusted to that corner and arranged in an appropriate manner.

In some embodiments, as shown in FIG. 6, a width of each of the slots S gradually decreases and then increases along a direction from one of adjacent two of the channels C to the other.

In some embodiments, as shown in FIG. 2, the casing 10 may, for example, further have a distribution chamber 14 and a plurality of impingement channels 15. The inlet 11 communicates with the distribution chamber 14, and the distribution chamber 14 communicates with the heat exchange chamber 12 through the impingement channels 15.

In some embodiments, as shown in FIG. 2, the distribution chamber 14, the impingement channels 15 and the heat exchange chamber 12 are, for example, sequentially located above one another, and the heat exchange chamber 12 is, for example, located closer to the heat source H than the distribution chamber 14 and the impingement channels 15.

In some embodiments, as shown in FIGS. 2 and 3, the casing 10 has a first inner surface 16 and a second inner surface 17. The first inner surface 16 faces the distribution chamber 14, and the second inner surface 17 faces the heat exchange chamber 12. The impingement channels 15 extend from the first inner surface 16 to the second inner surface 17. Each of the impingement channels 15 extends along a direction D1 or D2 which is at an acute angle θ to a normal line N of the second inner surface 17, where the acute angle θ is greater than or equal to 1 degree and is smaller than or equal to 89 degrees. In some embodiments, the acute angle θ is greater than or equal to 1 degree and is smaller than or equal to 45 degrees. In some embodiments, the acute angle θ is greater than or equal to 25 degrees and is smaller than or equal to 45 degrees, such as 35 degrees. In some embodiments, each of the impingement channels 15 extends along the direction D1 or D2 which is at an acute angle θ to a direction G of gravity (e.g., parallel to the normal line N of the second inner surface 17), where the acute angle θ is greater than or equal to 1 degree and is smaller than or equal to 89 degrees. In some embodiments, the acute angle θ is greater than or equal to 1 degree and is smaller than or equal to 45 degrees. In some embodiments, the acute angle θ is greater than or equal to 25 degrees and is smaller than or equal to 45 degrees, such as 35 degrees.

In some embodiments, as shown in FIGS. 5 and 6, the impingement channels 15 are arranged in rows along straight line L2 which are parallel to and spaced from one another. In some other embodiments, the lines L2 are, for example but not limited to, perpendicular to the aforementioned straight lines L1. In other words, an arrangement direction (e.g., from left to right) of the impingement channels 15 in each row is perpendicular to an arrangement direction (e.g., from top to bottom) of the heat exchange structures 20 in each row, but the disclosure is not limited thereto. In some other embodiments, an arrangement direction of the impingement channels in each row may be parallel to an arrangement direction of the heat exchange structures in each row. In addition, the positions and the arrangement of the impingement channel 15 are not restricted in the disclosure and may be modified according to the position of the heat source H.

In some embodiments, as shown in FIG. 2, in adjacent two of the rows of the impingement channels 15, extension directions D1 of the impingement channels 15 in one row are not parallel to extension directions D2 of the impingement channels 15 in the other row. In some embodiments, the extension directions D1 of the impingement channels 15 in one row intersect the extension directions D2 of the impingement channels 15 in the other row.

In some embodiments, as shown in FIG. 6, the extension directions D1 or D2 of the impingement channels 15 (e.g., from left to right or from right to left) have a tendency to be perpendicular to an arrangement direction A of the heat exchange structures 20 in each row.

After a coolant entering into the cold plate 1 from the inlet 11, the coolant sequentially flows through the distribution chamber 14 and the impingement channels 15 and then reaches the heat exchange chamber 12, such that the coolant performs heat exchange with the heat exchange structures 20. Then, the coolant leaves the cold plate 1 from the outlet 13 so as to take heat away.

The heat exchange structures 20 are located in the heat exchange chamber 12 and arranged in rows, the channels C are formed between the rows of heat exchange structures 20, the heat exchange structures 20 in each row are separated from each other so as to form the slots S, the slots S communicate with adjacent two of the channels C, and each of the slots S is formed by the curved edges E of adjacent two of the heat exchange structures 20 in each row. This configuration allows the cold plate 1 to have more surface area in contact with the coolant and induces turbulence in the coolant, thereby enhancing the heat exchange efficiency to deal with the increasing amount of heat generated by the heat source H.

Additionally, through the arrangement of the impingement channels 15, the coolant can be evenly distributed in the heat exchange chamber 12 after passing through the impingement channels 15, allowing the sufficient heat exchange between the coolant and the heat exchange structures 20, thereby further enhancing heat exchange efficiency. Furthermore, the arrangement of the impingement channels 15 can reduce pressure drop, thereby decreasing thermal resistance.

Moreover, the extension directions D1 or D2 (from left to right) of the impingement channels 15 have a tendency to be perpendicular to the arrangement direction A (from top to bottom) of the heat exchange structures 20 in each row. This configuration can enhance the turbulence effect, further improving heat exchange efficiency.

Referring to Table 1, table 1 shows simulation results of the cold plate 1 of one embodiment of the disclosure and a cold plate without impingement channel and with the heat exchange structures as sheet-shaped fins under the same conditions. From Table 1, the heat exchange efficiency, the pressure drops and the thermal resistance of the cold plate 1 are significantly improved.

TABLE 1
Simulation conditions

| Temperature (° C.) of coolant | 45 | |
|---|---|---|
| in the inlet | | |
| Type of coolant | water | |
| Flow rate (LPM) of coolant | 2.4 | |
| Power (W) of heat source | 1600 | |
| Type of cold plate | Cold plate without | Cold plate 1 |
| | impingement channel and | |
| | with the heat exchange | |
| | structures as sheet-shaped | |
| | fins | |
| Maximum temperature (° C.) | 67.3 | 63.2 |
| of casing of heat source | | |
| Average temperature (° C.) | 61 | 59.1 |
| of casing of heat source | | |
| Thermal resistance (° C./W) | 0.011 | 0.0108 |
| Pressure drop (psi) | 1.98 | 1.93 |

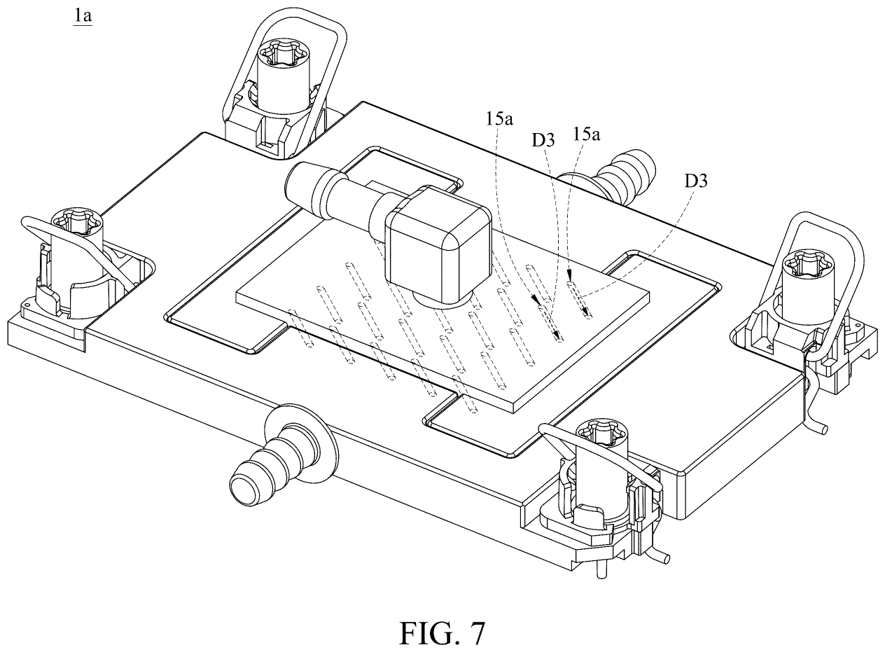

Then, referring to FIG. 7, FIG. 7 shows a perspective view of a cold plate 1a according to some embodiments of the disclosure. The structural configurations shown in FIG. 7 can be applied to other embodiments of the disclosure.

The cold plate 1a shown in FIG. 7 is similar to the cold plate 1 shown in FIG. 1, and the main difference between them is extension directions of the impingement channels, and thus the follow paragraph mainly introduces impingement channels 15a of the cold plate 1a while other parts of the cold plate 1a can be referred to the aforementioned paragraphs and will not be repeatedly introduced hereinafter.

In the cold plate 1a shown in FIG. 7, the impingement channels 15a in different rows extend along directions D3 parallel to each other; that is, inclined directions of the impingement channels 15a in these rows are the same.

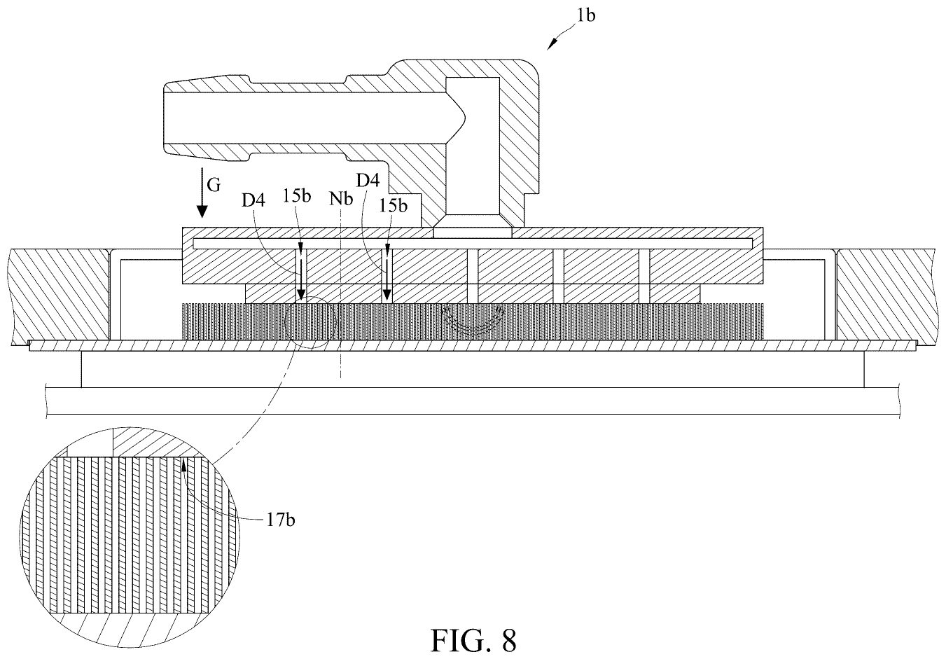

Then, referring to FIG. 8, FIG. 8 shows a cross-sectional view of a cold plate 1b according to some embodiments of the disclosure. The structural configurations shown in FIG. 8 can be applied to other embodiments of the disclosure.

The cold plate 1b shown in FIG. 8 is similar to the cold plate 1a of the previous embodiment, and the main difference between them is extension directions of the impingement channels, and thus the follow paragraph mainly introduces impingement channels 15b of the cold plate 1b while other parts of the cold plate 1b can be referred to the aforementioned paragraphs and will not be repeatedly introduced hereinafter.

In the cold plate 1b shown in FIG. 8, the impingement channels 15b in each row extend along directions D4 parallel to a normal line Nb of a second inner surface 17b. In some embodiments, the impingement channels 15b in each row extend along the directions D4 parallel to a direction G of gravity. For example, the impingement channels 15b in each row are vertical channels.

Note that the extension directions of the impingement channels in the aforementioned embodiments are not restricted to being all parallel to the normal line of the second inner surface or at the acute angles to the normal line of the second inner surface. In some other embodiments, the extension directions of the impingement channels may be partially parallel to the normal line of the second inner surface or at the acute angles to the normal line of the second inner surface.

Moreover, the impingement channels and the distribution chamber are optional structures and may be omitted in some other embodiments. In such a configuration, the inlet may directly communicate with the heat exchange chamber.

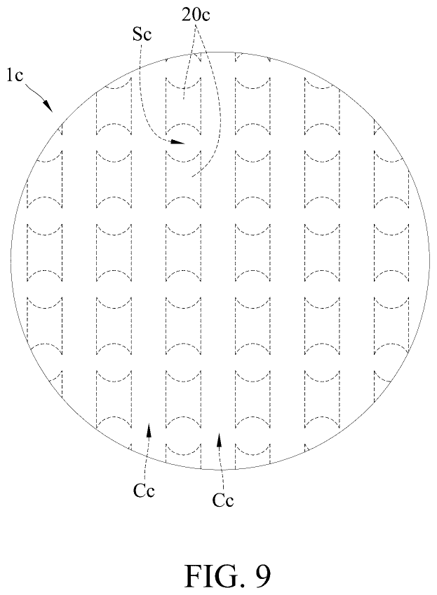

Then, referring to FIG. 9, FIG. 9 shows a partially enlarged top view of a cold plate 1c according to some embodiments of the disclosure. The structural configurations shown in FIG. 9 can be applied to other embodiments of the disclosure.

The cold plate 1c shown in FIG. 9 is similar to the cold plate 1 of the previous embodiment, and the main difference between them is the shapes of the slots in each row of the heat exchange structures, and thus the follow paragraph mainly introduces slots Sc in each row of heat exchange structures 20c of the cold plate 1c while other parts of the cold plate 1c can be referred to the aforementioned paragraphs and will not be repeatedly introduced hereinafter.

In each row of the heat exchange structures 20c of the cold plate 1c shown in FIG. 9, the width of each of the slots Sc between the heat exchange structures 20c gradually increases and then decreases along a direction from one of adjacent two of channels Cc to the other.

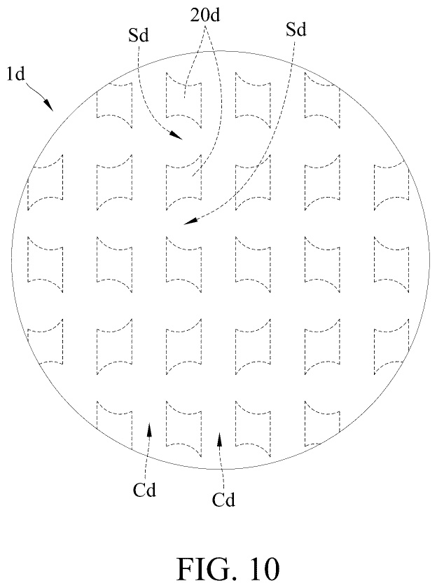

Then, referring to FIG. 10, FIG. 10 shows a partially enlarged top view of a cold plate 1d according to some embodiments of the disclosure. The structural configurations shown in FIG. 10 can be applied to other embodiments of the disclosure.

The cold plate 1d shown in FIG. 10 is similar to the cold plate 1 of the previous embodiment, and the main difference between them is the shapes of the slots in each row of the heat exchange structures, and thus the follow paragraph mainly introduces slots Sd in each row of heat exchange structures 20d of the cold plate 1d while other parts of the cold plate 1d can be referred to the aforementioned paragraphs and will not be repeatedly introduced hereinafter.

In each row of the heat exchange structures 20d of the cold plate 1d shown in FIG. 10, the width of each of the slots Sd between the heat exchange structures 20d gradually decreases or increases along a direction from one of adjacent two of channels Cd to the other.

According to the cold plates as discussed in the above embodiments, the heat exchange structures are located in the heat exchange chamber and arranged in rows, the channels are formed between the rows of heat exchange structures, the heat exchange structures in each row are separated from each other so as to form the slots, the slots communicate with adjacent two of the channels, and each of the slots is formed by the curved edges of adjacent two of the heat exchange structures in each row. This configuration allows the cold plate to have more surface area in contact with the coolant and induces turbulence in the coolant, thereby enhancing the heat exchange efficiency to deal with the increasing amount of heat generated by the heat source.

Additionally, through the arrangement of the impingement channels, the coolant can be evenly distributed in the heat exchange chamber after passing through the impingement channels, allowing the sufficient heat exchange between the coolant and the heat exchange structures, thereby further enhancing heat exchange efficiency. Furthermore, the arrangement of the impingement channels can reduce pressure drop, thereby decreasing thermal resistance.

Moreover, the extension directions (from left to right) of the impingement channels have a tendency to be perpendicular to the arrangement direction (from top to bottom) of the heat exchange structures in each row. This configuration can enhance the turbulence effect, further improving heat exchange efficiency.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A cold plate, configured to be thermally coupled to a heat source, comprising:
a casing, having an inlet, a heat exchange chamber and an outlet, wherein the inlet and the outlet communicate with the heat exchange chamber; and
a plurality of heat exchange structures, located in the heat exchange chamber and arranged in rows, wherein a plurality of channels are formed between the rows of the plurality of heat exchange structures, the plurality of heat exchange structures in each row are spaced apart from one another so as to form a plurality of slots, the plurality of slots communicate with adjacent two of the plurality of channels, and each of the plurality of slots are formed by curved edges of adjacent two of the plurality of heat exchange structures in each row.

2. The cold plate according to claim 1, wherein a width of each of the plurality of slots gradually decreases and then increases along a direction from one of the adjacent two of the plurality of channels to the other.

3. The cold plate according to claim 1, wherein a width of each of the plurality of slots gradually increases and then decreases along a direction from one of the adjacent two of the plurality of channels to the other.

4. The cold plate according to claim 1, wherein a width of each of the plurality of slots gradually increases or decreases along a direction from one of the adjacent two of the plurality of channels to the other.

5. The cold plate according to claim 1, wherein the plurality of heat exchange structures are arranged in an array.

6. The cold plate according to claim 1, wherein the plurality of heat exchange structures are arranged in the rows along straight lines which are parallel to and spaced apart from one another.

7. The cold plate according to claim 1, wherein the casing further has a distribution chamber and a plurality of impingement channels, the inlet communicates with the distribution chamber, and the distribution chamber communicates with the heat exchange chamber through the plurality of impingement channels.

8. The cold plate according to claim 7, wherein the plurality of impingement channels are arranged in rows along straight lines which are parallel to and spaced apart from one another.

9. The cold plate according to claim 7, wherein the casing has a first inner surface and a second inner surface, the first inner surface faces the distribution chamber, the second inner surface faces the heat exchange chamber, the plurality of impingement channels extend from the first inner surface to the second inner surface, and at least one of the plurality of impingement channels extends along a direction parallel to a normal line of the second inner surface.

10. The cold plate according to claim 7, wherein the casing has a first inner surface and a second inner surface, the first inner surface faces the distribution chamber, the second inner surface faces the heat exchange chamber, the plurality of impingement channels extend from the first inner surface to the second inner surface, and at least one of the plurality of impingement channels extends along a direction at an acute angle to a normal line of the second inner surface.

11. The cold plate according to claim 10, wherein the acute angle is greater than or equal to 1 degree and is smaller than or equal to 89 degrees.

12. The cold plate according to claim 11, wherein the acute angle is greater than or equal to 1 degree and is smaller than or equal to 45 degrees.

13. The cold plate according to claim 12, wherein the acute angle is greater than or equal to 25 degrees and is smaller than or equal to 45 degrees.

14. The cold plate according to claim 13, wherein the acute angle is 35 degrees.

15. The cold plate according to claim 8, wherein the casing has a first inner surface and a second inner surface, the first inner surface faces the distribution chamber, the second inner surface faces the heat exchange chamber, the plurality of impingement channels extend from the first inner surface to the second inner surface, and each of the plurality of impingement channels extends along a direction at an acute angle to a normal line of the second inner surface.

16. The cold plate according to claim 15, wherein in adjacent two of the rows of the plurality of impingement channels, extension directions of the plurality of impingement channels in one row are not parallel to extension directions of the plurality of impingement channels in the other row.

17. The cold plate according to claim 7, wherein the distribution chamber, the plurality of impingement channels and the heat exchange chamber are sequentially located above one another.

18. The cold plate according to claim 7, wherein at least one of the plurality of impingement channels extends along a direction at an acute angle to a direction of gravity.

19. The cold plate according to claim 7, wherein at least one of the plurality of impingement channels extends along a direction parallel to a direction of gravity.
